(19) United States
(12) Patent Application Publication
(10) Pub. No.: US 2003/0034546 A1
(43) Pub. Date: Feb. 20, 2003

(54) Multilayer microstructure macrocapacitor

(76) Inventors: Hung-Yi Lin, Hsin-Chu (TW); Hung-Yin Tsai, Hsin-Chu (TW); Chien-Chang Su, Kaohsiung (TW); Jung-Yen Huang, Chung-Li City (TW)

Correspondence Address: BACON & THOMAS, PLLC, 625 SLATERS LANE, FOURTH FLOOR, ALEXANDRIA, VA, 22314

(21) Appl. No.: 09/929,086

(22) Filed: Aug. 15, 2001

(51) Int. Cl. H01L 29/00

(52) U.S. Cl. 257/532

(57) ABSTRACT

The present invention is to provide a kind of multilayer microstructure macrocapacitor, wherein on one side of an electrode substrate after it forms slots with an appropriate aspect ratio, sequentially forms a high dielectric layer and a conducting material layer to give a basic composition unit, laminates the conducting material layers of two groups of basic composition unit to form a monolayer microstructure macrocapacitor, and stacking laminates the plural groups of the monolayer microstructure macrocapacitor to obtain a multilayer microstructure macrocapacitor; on two sides of an electrode substrate it forms a basic composition unit of a microstructure macrocapacitor through the process described above, and laminates the plural groups of the monolayer microstructure macrocapacitor to obtain a multilayer microstructure macrocapacitor.

### BACKGROUND OF INVENTION

1. Field of Invention

The present invention is to provide a kind of multilayer microstructure macrocapacitor, wherein by using microdeveloping and etching method on one side of an electrode substrate after it forms slots with an appropriate aspect ratio (depth-width ratio), sequentially forms a high dielectric layer and a conducting material layer, and laminates the plural groups to obtain a having an appropriate capacitance multilayer microstructure macrocapacitor.

2. Description of The Prior Art

In the modern mobile communication system, for example: cellular phone, bluetooth module, mobile network browser, global position system (GPS), personal digital assistant (PDA), and B. B. Call, etc., all these products have light, thin, short, and small etc. demands, therefore for them the volume of various electronic devices also needs to become much smaller simultaneously.

Capacitor is a necessary passive element in various electronic devices. According to the capacitance equation:

C=k∈₀A/d

It illustrates that the capacitance is directly proportional to a dielectric constant and the surface area of an electrode, and is inversely proportional to the thickness of dielectric layer. Hence, if it reduces the volume of capacitor and increases the capacitance of capacitor, it is necessary to have a high dielectric constant, to increase the surface area of electrode, and to reduce the thickness of dielectric layer.

FIG. 1 illustrates a cross-sectional view of a known MLCC capacitor, wherein there increases several electrode layers 1 and dielectric layers 21, that is the method of increasing capacitance, it refers to the major method of increasing the surface area of capacitor. In the capacitor there increases the surface area of capacitor by using a multiplayer method, its effect is in accordance with the parallel multiple capacitors; however, stacking laminates multilayers technique is reaching the limit, and it is not possible to reduce the capacitor volume, and also it is unable to increase the capacitance of capacitor. Microstrcture capacitor refers to the change of the original flat surface to be the slots of a three dimensional structure to increase the surface areas, however, in the holes with a high aspect ratio (depth-width ratio) the depositing film technique is very difficult, and the manufacturing cost is very high.

### SUMMARY OF THE INVENTION

Hence, the aim of the present invention is to solve the drawbacks described above. In order to avoid the presence of the drawbacks described above, the present invention is to provide a kind of multilayer microstructure macrocapacitor, wherein it increases the surface area with microstructrue.

The other aim of the present invention is to provide a kind of multilayer microstructure macrocapacitor, wherein it forms a high dielectric thin-film.

The other aim of the present invention is to provide a kind of multilayer microstructure macrocapacitor, wherein it reduces the difficulty of the depositing film with an appropriate high aspect ratio (depth-width ratio), and it does not reduce the capacitance by using the laminating technique.

In order to obtain the aims descried above, the present invention refers to a kind of multilayer microstructure macrocapacitor. The present invention is to provide a kind of multilayer microstructure macrocapacitor, wherein on one side of an electrode substrate it forms slots with an appropriate aspect ratio (depth-width ratio) by using microdeveloping and etching methods, after removing the photoresisting layer, sequentially it forms a high dielectric layer and a conducting material layer to give a basic composition unit, and laminates the conducting material layers of two groups of basic composition unit to form a monolayer-type of microstructure macrocapacitor, and stacking laminates the plural groups of the monolayer microstructure macrocapacitor to obtain a multilayer microstructure macrocapacitor; on two sides of an electrode substrate it forms a basic composition unit of a microstructure macrocapacitor through the process described above, and laminates the plural groups of the monolayer microstructure macrocapacitor to obtain a multilayer microstructure macrocapacitor.

It is able to increase the surface area, to form a high dielectric thin-film, and not to reduce the capacitance.

### BRIEF DESCRIPTION OF THE DRAWINGS

FIG. 1 illustrates the cross-sectional view of a known MLCC capacitor.

FIGS. 2a, 2b, 2c, 2d, 2e, and 2f illustrate the cross-sectional views of manufacturing flow chart for the multilayer microstructure macrocapacitor of the present invention.

FIG. 3 illustrates the cross-sectional view of the other example of the present invention.

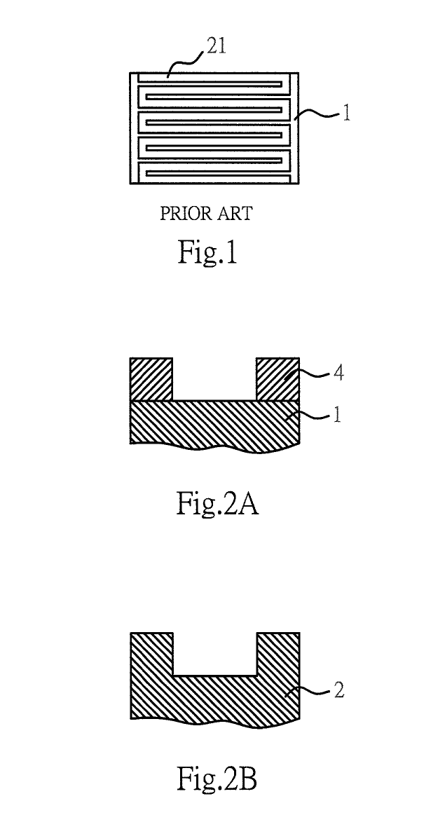

### DETAILED DESCRIPTION OF THE PREFERRED EMBODIMENTS

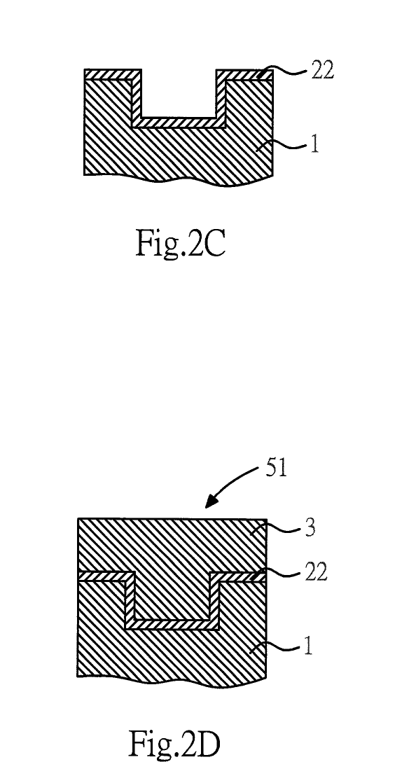

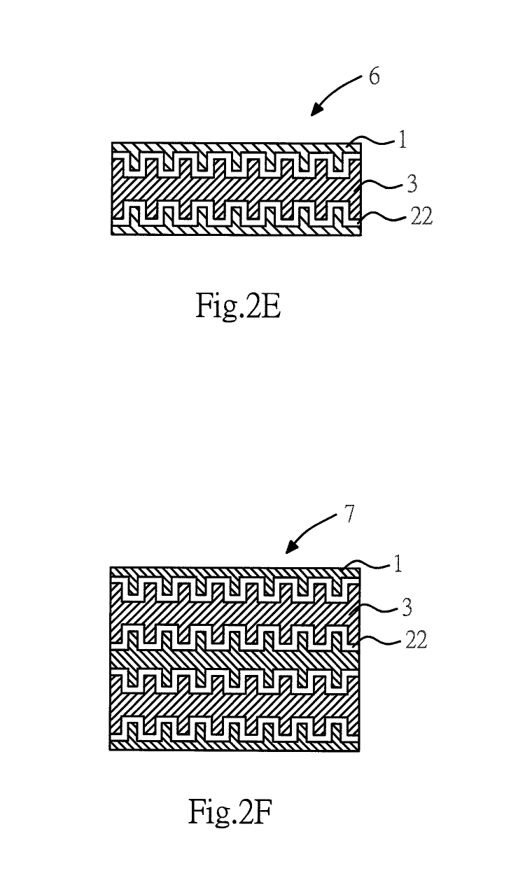

FIGS. 2a, 2b, 2c, 2d, 2e, and 2f illustrate the cross-sectional view of manufacturing flow chart for the multilayer microstructure macrocapacitor of the present invention, wherein on one side of a thickness 0.02˜0.5 mm n-type Si, p-type Si or Au, Cu metallic electrode substrate 1 it forms a having picture photoresisting layer 4 by using a microdeveloping process; through an etching process on the electrode substrate 1, it can etch the appropriate slots with a width 0.002˜0.1 mm, depth 0.002˜0.5 mm, and a aspect ratio (depth-width ratio 1:1˜50:1) by using electrochemical etching, wet etching, or dry etching. After removing the photoresisting layer 4, it forms a thickness 10˜500 nm high dielectric layer 22 and a thickness 100˜2000 nm conducting material layer 3 by using physical vapor deposition (PVD) or chemical vapor deposition (CVD) method. Sequentially, it forms a thickness 10˜500 nm high dielectric layer 22 and a thickness 100˜2000 nm conducting material layer 3 on the surface of an electrode substrate 1 to obtain a microstructure macrocapacitor basic composition unit 51. It laminates two groups of conducting material layers 3 of microstructure macrocapacitor basic composition unit to form a monolayer microstructure macrocapacitor 6 by using a wafer bonding technology. After stacking the plural groups of monolayer microstructure macrocapacitor, laminating at high temperature with metal, it obtains a multilayer microstructure macrocapacitor 7. Material of high dielectric layer 22 of multilayer microstructure macrocapacitor 7 can be selected from the following compounds: barium strontium titanate (BaₓSr₁₋ₓTiO₃, x=0˜1, BST), tantalum oxide, titanium oxide, lead zirconate titanate(Pb(Zr,Ti)O₃, PZT), lead lanthanum zirconate titanate((Pb,La)(Zr,Ti)O₃, PLZT), strontium bismuth tantalate(SrBi₂Ta₂O₉, SBT), diamond, and diamond-like, etc.; a conducting material layer 3 of multilayer microstructure macrocapacitor 7 can be the following metals: aluminum Al, platinum Pt, ruthenium Ru, titanium Ti, and tungsten W.

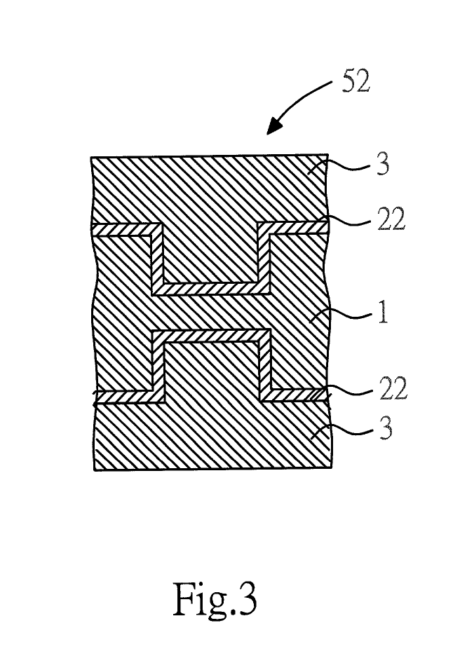

FIG. 3 illustrates the cross-sectional view of the other example of the present invention, wherein on two sides of an electrode substrate 1 by using a microdeveloping process and an etching process, it etches an appropriate slot with a width 0.002˜0.1 mm, depth 0.002˜0.5 mm, and a aspect ratio (depth-width ratio 1:1˜50:1). Afterwards, sequentially by using physical vapor deposition (PVD) or chemical vapor deposition method (CVD) it forms a thickness 10˜500 nm high dielectric layer 22 and a thickness 100˜2000 nm conducting material layer 3, and it forms a microstructure macrocapacitor basic composition unit 52. After stacking the plural groups of monolayer microstructure macrocapacitor, laminating at high temperature with metal, it obtains a multilayer microstructure macrocapacitor 7.

The present invention specially discloses and describes selected the best examples. It is to be understood, however, that the present invention is not limited to the specific features shown and described. The invention is claimed in any forms or modifications within the spirit and the scope of the appended claims.

What is claimed is:

1. A kind of multilayer microstructure macrocapacitor, comprising:
an electrode substrate;
a microdeveloping process and an etching process, on one side of an electrode substrate it forms slots with an appropriate aspect ratio;
removing the photoresisting layer;
a high dielectric layer forms on the surface of its electrode substrate;
a conducting material layer forms on the surface of its high dielectric layer;
by using the procedure described above, it forms a monolayer microstructure macrocapacitor, and laminates the plural groups of the monolayer microstructure macrocapacitor to obtain a monolayer microstructure macrocapacitor; and stacking laminates the plural groups of the monolayer microstructure macrocapacitor to obtain a having an appropriate capacitance multilayer microstructure macrocapacitor.

2. The multilayer microstructure macrocapacitor of claim 1, wherein said the thickness of an electrode substrate is in the range of 0.02˜0.5 mm.

3. The multilayer microstructure macrocapacitor of claim 1, wherein said the width of slot of an electrode substrate is in the range of 0.002˜0.1 mm.

4. The multilayer microstructure macrocapacitor of claim 1, wherein said the depth of slot of an electrode substrate is in the range of 0.002˜0.5 mm.

5. The multilayer microstructure macrocapacitor of claim 1, wherein said the aspect ratio (depth-width ratio) of slot of an electrode substrate is 1:1˜50:1.

6. The multilayer microstructure macrocapacitor of claim 1, wherein said the thickness of a high dielectric layer is in the range of 10˜500 nm.

7. The multilayer microstructure macrocapacitor of claim 1, wherein said material of the high dielectric layer can be selected from the following compounds: barium strontium titanate (BaₓSr₁₋ₓTiO₃, x=0˜1, BST), tantalum oxide, titanium oxide, lead zirkonate titanate(Pb(Zr,Ti)O₃, PZT), lead lanthanum zirconate titanate((Pb,La)(Zr,Ti)O₃, PLZT), strontium bismuth tantalate(SrBi₂Ta₂O₉, SBT), diamond, and diamond-like, etc.

8. The multilayer microstructure macrocapacitor of claim 1, wherein said the thickness of a conducting material layer is in the range of 100˜2000 nm.

9. The multilayer microstructure macrocapacitor of claim 1, wherein said there laminates the conducting material layers of two groups of basic composition unit to form a monolayer-type microstructure macrocapacitor, and the laminating method is a wafer bonding technology.

10. The multilayer microstructure macrocapacitor of claim 1, wherein said there stacking laminates the plural groups of the monolayer microstructure macrocapacitor, and the laminating method is to bind at high temperature with metal.

11. A kind of multilayer microstructure macrocapacitor, comprsing:
an electrode substrate;
a microimaging process and an etching process, on two sides of an electrode substrate it forms slots with an appropriate width-depth ratio;
removing the photoresisting layer;
a high dielectric layer forms on two sides of its electrode substrate;
a conducting material layer forms on two sides of its high dielectric layer;
by using the procedure described above, it forms a monolayer-type of microstructure macrocapacitor, and laminates the plural groups of the monolayer microstructure macrocapacitor to obtain a multilayer microstructure macrocapacitor; and stacking laminates the plural groups of the monolayer microstructure macrocapacitor to obtain a having an appropriate capacitance multilayer microstructure macrocapacitor.

12. The multilayer microstructure macrocapacitor of claim 11, wherein said the thickness of an electrode substrate is in the range of 0.02˜0.5 mm.

13. The multilayer microstructure macrocapacitor of claim 11, wherein said the width of slot of an electrode substrate is in the range of 0.002˜0.1 mm.

14. The multilayer microstructure macrocapacitor of claim 11, wherein said the depth of slot of an electrode substrate is in the range of 0.002˜0.5 mm.

15. The multilayer microstructure macrocapacitor of claim 11, wherein said the aspect ratio (depth-width ratio) of slot of an electrode substrate is 1:1˜50:1.

16. The multilayer microstructure macrocapacitor of claim 11, wherein said the thickness of a high dielectric layer is in the range of 10˜500 nm.

17. The multilayer microstructure macrocapacitor of claim 11, wherein said material of the high dielectric layer can be selected from the following compounds: barium strontium titanate (BaₓSr₁₋ₓTiO₃, x=0˜1, BST), tantalum oxide, titanium oxide, lead zirconate titanate(Pb(Zr,Ti)O₃, PZT), lead lanthanum zirconate titanate((Pb,La)(Zr,Ti)O₃, PLZT), strontium bismuth tantalate(SrBi₂Ta₂O₉, SBT), diamond, and diamond-like, etc.

18. The multilayer microstructure macrocapacitor of claim 11, wherein said the thickness of a conducting material layer is in the range of 100˜200 nm.

19. The multilayer microstructure macrocapacitor of claim 11, wherein said there stacking laminates the plural group of the monolayer-type of microstructure macrocapacitor, and the laminating method is to bind at high temperature with metal.
